(19) United States
(12) Patent Application Publication
(10) Pub. No.: US 2009/0097301 A1
(43) Pub. Date: Apr. 16, 2009

(54) SEMICONDUCTOR STORAGE APPARATUS AND SEMICONDUCTOR INTEGRATED CIRCUIT INCORPORATING THE SAME

(75) Inventors: Eiji Takahashi, Nara (JP); Yoshiyuki Saito, Osaka (JP)

Correspondence Address: WENDEROTH, LIND & PONACK L.L.P., 2033 K. STREET, NW, SUITE 800, WASHINGTON, DC, 20006, US

(73) Assignee: MATSUSHITA ELECTRIC INDUSTRIAL CO., LTD., Osaka (JP)

(21) Appl. No.: 11/915,816

(22) PCT Filed: May 18, 2006
(86) PCT No.: PCT/JP2006/309912

§ 371 Date: Nov. 28, 2007

(30) Foreign Application Priority Data
Jun. 1, 2005 (JP) 2005-160965

(51) Int. Cl. G11C 11/24; G11C 7/00

(52) U.S. Cl. 365/149; 365/189.08

(57) ABSTRACT

An object is to provide a semiconductor memory device which can dynamically change the number of memory cells used as by-pass capacitors. In each memory block, one selector signal line is provided in parallel to one word line. In a pair of the word line and the selector signal line adjacent to each other, states are maintained opposite to each other. Further, in a memory block, one branch of a supply line is provided in parallel to one bit line. In each of the memory cells, a first transistor connects a capacitor to the bit line in accordance with the state of the word line. Furthermore, a second transistor connects the same capacitor to the branch of the supply line in accordance with the state of the selector signal line. In the memory cells aligned in a row direction, gates of the first transistors are connected to the same word line, and gates of the second transistors are connected to the same selector signal line.

### TECHNICAL FIELD

The present invention relates to a semiconductor memory device, particularly, a semiconductor memory device incorporated into a semiconductor integrated circuit.

### BACKGROUND ART

Dynamic semiconductor memory devices (DRAMs) have a feature that their density of integration and/or capacity can be readily increased. In recent years, use of a DRAM integrated on the same chip as a logic circuit (embedded DRAM) has become more common. Particularly, the embedded DRAM has a high data transfer speed. Thus, it is suitable for a system LSI which performs rapid calculation and/or communication of a large amount of data (for example, graphics LSI). On the other hand, the embedded DRAM involves a process more complicated than that of a normal DRAM. As a conventional technique for simplifying the DRAM embedding process, the technique described below is known (see Japanese Laid-Open Publication No. 2003-332532, for example). In a DRAM according to the conventional technique, in a part of a memory cell array, capacitors of memory cells are diverted to by-pass capacitors (smoothing capacity) as described below (see FIG. 2). Connection terminals Bᵢ₊₁, Bᵢ, and Bᵢ₋₁, of a plurality of bit lines 206, 207, and 208 are connected to a supply line VDD. On the other hand, connection terminals Wᵢ and Wᵢ₊₁ of word lines 203 and 204 are maintained at a predetermined potential VWL. The potential VWL maintains transfer gates 201 included in memory cells at ON state. As a result, capacitors 202 of the memory cells are connected to the supply line VDD via the transfer gates 201 and the bit lines 206, 207, and 208. In this way, the capacitors 201 of the memory cells serve as by-pass capacitors added between the supply line VDD and ground to suppress a potential change of the supply line VDD. Compared to interlayer capacity and/or interline capacity of a MOS transistor, which is usually used as a by-pass capacitor, the ratio of capacity to an element area is generally high in the capacitors of the memory cells. Therefore, it becomes possible to omit a process related to by-pass capacitors from the DRAM embedding process while the area is being kept small and a large smoothing capacity are secured.

### DISCLOSURE OF THE INVENTION

### Problems to be Solved by the Invention

In the conventional DRAM as described above, potentials of the bit lines and the word lines connected to the memory cells used as by-pass capacitors are fixed. Thus, these memory cells completely lose their original function as memory (capability to store bit information). In other words, the total number of the memory cells used as by-pass capacitors is constant and unchangeable. On the other hand, the number of the memory cells actually used for storing bit information among the memory cells included in the DRAM generally varies depending upon applications, environment, and operating conditions. Therefore, in order to further improve usage efficiency of the memory cells to realize further effective reduction in the area of the DRAM, the number of the memory cells used as the by-pass capacitors should be changed dynamically depending upon the performance required by the application, environment, and use condition of the memory.

An object of the present invention is to provide a semiconductor memory device which can dynamically change the number of the memory cells used as by-pass capacitors.

### Means for Solving the Problems

A semiconductor memory device according to the present invention can connect and disconnect capacitors of memory cells to and from a supply line. With such a structure, the number of the capacitors connected to the supply line and used as by-pass capacitors can be changed. Preferably, the semiconductor memory device includes:

a plurality of bit lines lined in parallel;

a plurality of word lines lined in parallel along a direction orthogonal to the bit lines;

a first transistor which is controlled by one of the word lines, and connects one of the capacitors to one of the bit lines;

a second transistor for connecting one of the capacitors to the supply line; and

a selector signal line for controlling the second transistor. Further preferably, a predetermined number of the second transistors are controlled by the same selector signal line. Preferably, one selector signal line is provided one for a predetermined number of the word lines. The supply line connected to the second transistor may be different for each group of the memory cells connected to a predetermined number of the bit lines or the word lines.

A semiconductor memory device according to the present invention may include a third transistor for connecting one of the bit lines to the supply line instead of the second transistor. In such a case, a selector signal line controls the third transistor. Preferably, a predetermined number of the third transistors are controlled by the same selector signal line. The third transistor may connect a plurality of the bit lines to the same supply line.

In the above-mentioned semiconductor memory device according to the present invention, the capacitors of the memory cell function as by-pass capacitors when the second or the third transistor is on, and function as memory when the second or the third transistor is off. Therefore, the semiconductor memory device has the capacitors of the memory cells which are not used for storing bit information function as the by-pass capacitors, and can suppress a potential change of the supply line. Further, since ON/OFF states of the second or third transistors can be controlled by the selector signal line, the number of the capacitors in the memory cell which are used as the by-pass capacitors can be changed dynamically in units of cells, units of words, or units of blocks.

A semiconductor integrated circuit according to the present invention includes the above-mentioned semiconductor memory device according to the present invention, and changes the number of the capacitors to be connected to the supply line among the capacitors of the memory cells in accordance with a process. Preferably, the semiconductor integrated circuit further includes:

a logic circuit unit (preferably, a CPU) for running predetermined applications; and

a memory control unit for controlling the semiconductor memory device in accordance with an instruction from the logic circuit unit, and particularly for changing the number of the capacitors to be connected to the supply line in accordance with a process. Preferably, the memory control unit controls the selector signal line in accordance with a process. Alternatively, the semiconductor memory device may further include a register for controlling the selector signal line and the memory control unit may control the register in accordance with a process.

The above-mentioned semiconductor integrated circuit according to the present invention connect capacitors which are not used for storing bit information among the capacitors included in the memory cells of the above-mentioned semiconductor memory device to the supply line to have them function as the by-pass capacitors, and suppresses a potential change of the supply line. The semiconductor integrated circuit can control particularly the selector signal lines directly or by using the above-mentioned register. Therefore, the number of the capacitors of the memory cells used as the by-pass capacitors can be preferably changed dynamically in any units depending upon performance required by the applications, environment, and use conditions of memory.

### EFFECTS OF THE INVENTION

As described above, in the semiconductor integrated circuit according to the present invention, it is possible to dynamically change the number of capacitors used as by-pass capacitors among the capacitors included in memory cells of the semiconductor memory device incorporated therein. Therefore, in the semiconductor memory device, efficiency in use of the memory cells can be further improved readily from that in a semiconductor memory device incorporated into a conventional semiconductor integrated circuit. Thus, further reduction in effective area can be achieved. Moreover, since restrictions on the semiconductor memory device by the applications and/or environment are relatively loose, the above-mentioned semiconductor integrated circuit according to the present invention allows flexibility in designing. As described above, the semiconductor integrated circuit can efficiently suppress a potential change of a power supply, so it is useful particularly as a system LSI for a digital TV which requires a high-speed operation. Furthermore, the semiconductor memory device according to the present invention is advantageous in application to DRAMs which allow high-speed access.

### BRIEF DESCRIPTION OF THE DRAWINGS

FIG. 1 is a block diagram showing a semiconductor memory device according to the first embodiment of the present invention.

FIG. 2 is a block diagram showing a conventional semiconductor memory device.

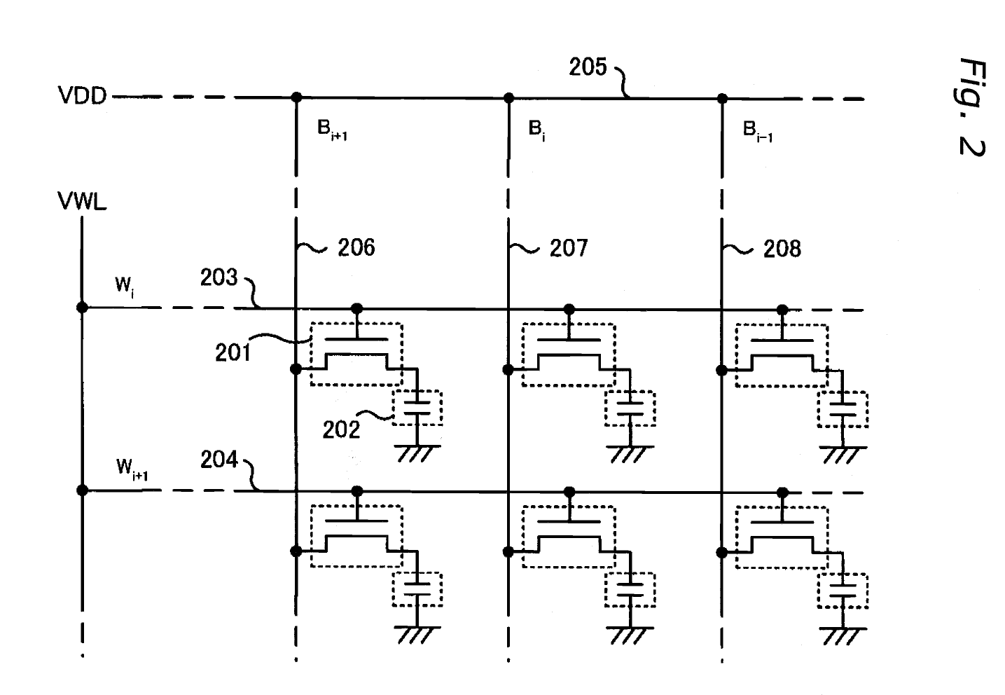

FIG. 3 is a block diagram showing a semiconductor memory device according to the second embodiment of the present invention.

FIG. 4 is a block diagram showing a hardware structure of the semiconductor memory device according to the first embodiment of the present invention.

FIG. 5 is a block diagram showing a software structure of the semiconductor memory device according to the first embodiment of the present invention.

FIG. 6 is a block diagram showing a hardware structure of a semiconductor memory device according to the third embodiment of the present invention.

### BEST MODE FOR CARRYING OUT THE INVENTION

Hereinafter, best modes for carrying out the present invention will be described with reference to the drawings.

### First Embodiment

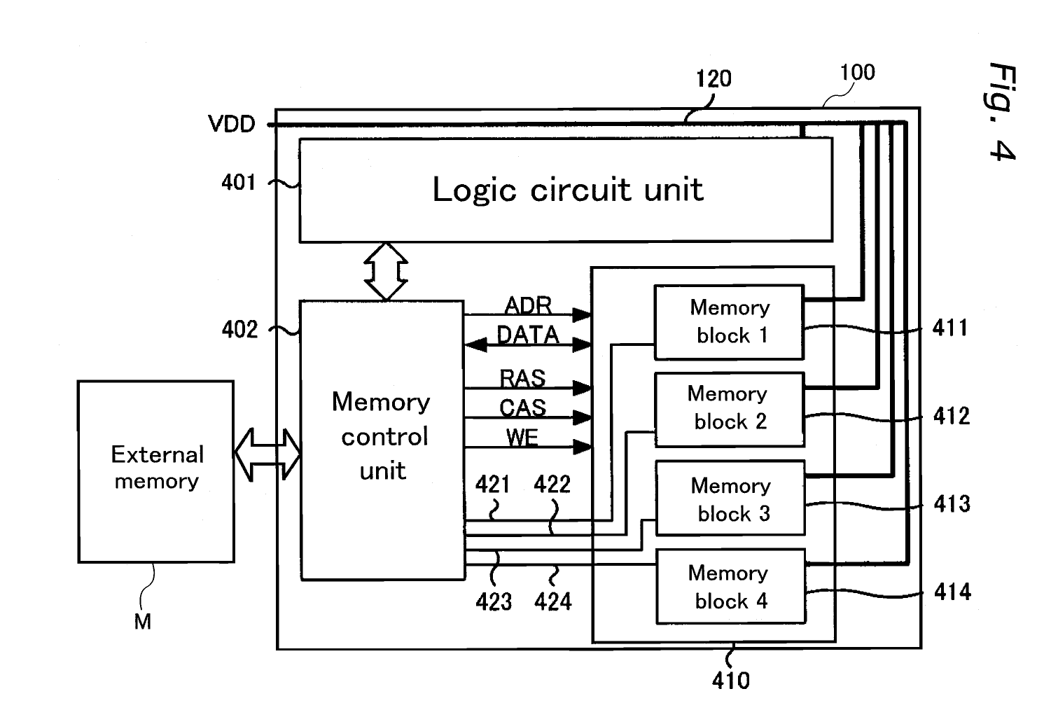

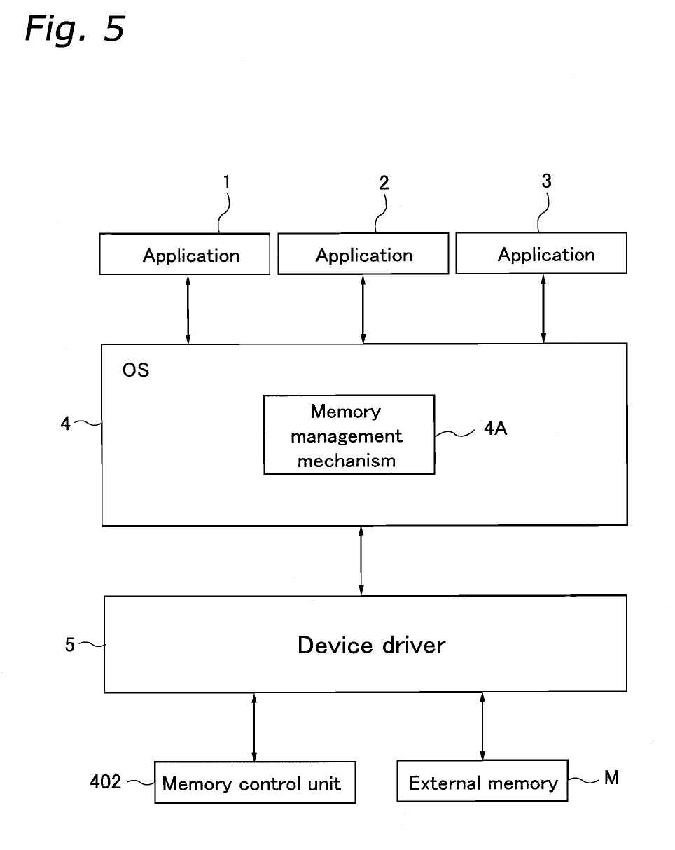

A semiconductor integrated circuit 100 according to the first embodiment of the present invention is preferably a system LSI, and includes a supply line 120, a logic circuit unit 401, a memory control unit 402, and a semiconductor memory device (hereinafter, referred to as a memory core unit) 410 (see FIG. 4). The supply line 120 is maintained at a constant supply potential VDD, and supply power to the components in the semiconductor integrated circuit 100. The logic circuit unit 401 is preferably a CPU, and is connected to the components in the semiconductor integrated circuit 100 via internal bus. The logic circuit unit 401 runs various programs (see FIG. 5) and controls operations of the components in the semiconductor integrated circuit 100.

The memory control unit 402 is connected particularly to the memory core unit 410 via the internal bus and to an external memory M located outside the semiconductor integrated circuit 100 via external bus (see FIG. 4). The external memory M is preferably a DDR-SDRAM or SRAM. The memory control unit 402 directly controls the external memory M and/or the memory core unit 410 in accordance with the instruction from the logic circuit unit 401. The memory control unit 402 sends predetermined groups of signals (address ADR, row address strobe RAS, column address strobe CAS, and write enable WE) particularly to the memory core unit 410, and controls data DATA exchanged between the memory control unit 402 and the memory core unit 410. Further, between the memory control unit 402 and the memory core unit 410, a plurality of selector signal lines 421, 422, 423, and 424 are connected.

The memory core unit 410 is preferably a DRAM, and is formed of a plurality of (four in FIG. 4) memory blocks 411, 412, 413, and 414 (see FIG. 4). The memory blocks 411 through 414 are connected to the supply line 120 and the selector signal lines 421 through 424. When any of the selector signal lines 421 through 424 is activated by the memory control unit 402, in a memory block connected to the selector signal line, capacitors of a predetermined number in the memory cells are connected to the supply line 120 and used as by-pass capacitors. On the other hand, in memory blocks connected to the selector signal lines 421 through 424 which are not active, capacitors in the memory cells are disconnected from the supply line 120 and store bit information as memory.

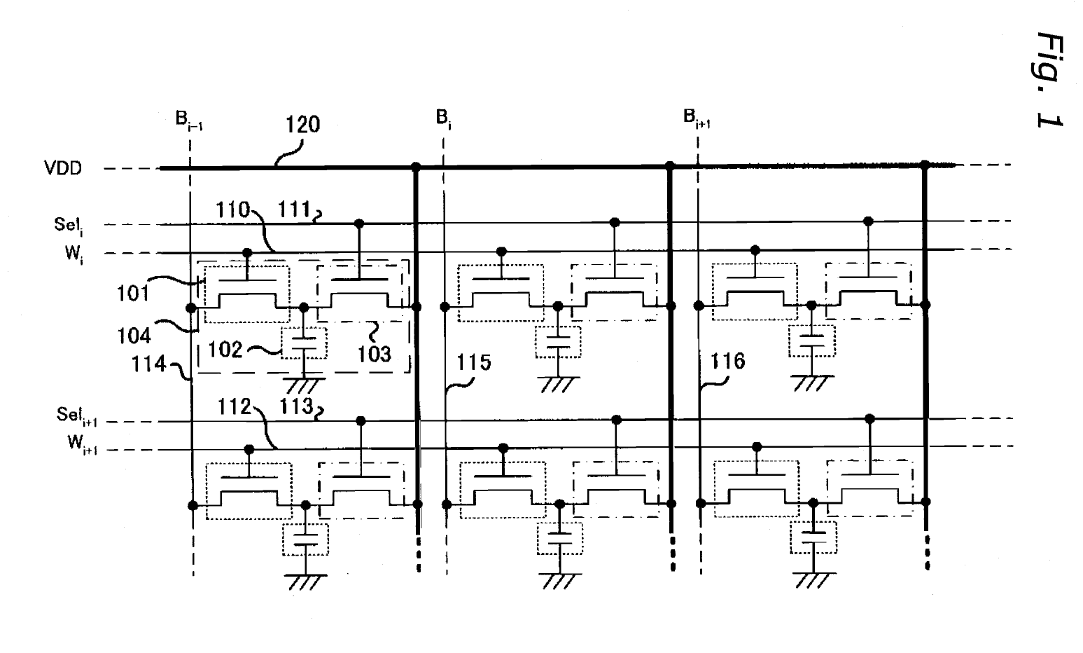

The memory blocks according to the first embodiment of the present invention preferably includes memory cells 104, word lines 110, 112, . . . , bit lines 114, 115, 116, . . . and selector signal lines 111, 113, . . . (see FIG. 1). The memory cells 104 are preferably arranged in a matrix and form a memory cell array. The word lines 110, 112, . . . extend in a horizontal direction (row direction of the memory cell array) between the memory cells 104. The bit lines 114, 115, . . . extend in a vertical direction (column direction of the memory cell array) between the memory cells 104. The selector signal lines 111, 113, . . . are provided one-by-one for the word lines 110, 112, . . . along a parallel direction, and extend in the row direction between the memory cells 104. Particularly, in a pair of the word line 110 and the selector signal line 111 adjacent to each other, they are maintained at opposite states: when one is active, the other is always inactive. In the memory block, the supply line 120 is further branched into a plurality of branches. The branches are provided respectively in parallel to the bit lines 110, 112, . . . , and extend in the column direction between the memory cells 104.

Each of the memory cells 104 includes a first transistor 101, a capacitor 102, and a second transistor 103 (see FIG. 1). The first transistor 101 is preferably a MOSFET having a gate connected to the closest word line 110, a source connected to the closest bit line 114 and a drain connected to one end of the capacitor 102. Another end of the capacitor 102 is grounded. A second transistor 103 is preferably a MOSFET having a gate connected to the closest selector signal line 111, a source connected to the closest branch of the supply line 120 and a drain connected to one end of the capacitor 102. In other words, in the memory cells 104 aligned in the row direction, gates of the first transistors 101 are connected to the same word line 110, and gates of the second transistors 103 are connected to the same selector signal line 111. On the other hand, in the memory cells 104 aligned in the column direction, sources of the first transistors 101 are connected to the same bit line 114, and sources of the second transistors 103 are connected to the same branch of the supply line 120.

When one of the selector signal lines, 111, is not active, the second transistors 103 connected to the selector signal line 111 (in other words, the second transistors 103 of the memory cells 104 included in one row of the memory cell array) are maintained at OFF state. Therefore, in the memory cells 104 included in the row of the memory cell array, the capacitors 102 function as memory by controlling ON/OFF state of the first transistors 101 by using the corresponding word line 110. Specifically, when the word line 110 is active, the bit line 114 and the capacitor 102 are conductive. As a voltage level of the bit line 114 is changed by a charge stored in the capacitor 102, the bit information stored in the capacitor 102 is read out from the change. On the other hand, when the bit line 114 has been pre-charged, the capacitor 102 is charged and bit information corresponding to the voltage level of the bit line 114 is stored in the capacitor 102.

When the selector signal line 111 mentioned above is active, the second transistors 103 connected to the selector signal line 111 are maintained at ON state. Therefore, in the memory cells 104 included in one row of the memory cell array, the capacitors 102 are connected to the supply line 120 and serve as by-pass capacitors irrespective of ON/OFF state of the first transistors, and/or states of the bit line 114. In this way, a potential change of the supply line 120 is suppressed.

Accordingly, in the memory blocks according to the first embodiment of the present invention, the capacitors 102 of the memory cells can function as both memory and by-pass capacitors depending upon the states of the selector signal lines 111, 113, . . . . Particularly, the number of capacitors used as by-pass capacitors can be changed in units of rows of memory cell array.

Unlike the arrangement shown in FIG. 1, one selector signal line may be provided for a plurality of word lines. In such a case, the number of capacitors used as the by-pass capacitors is changed with a plurality of rows of the memory cell array being one unit. Furthermore, a memory cell including a second transistor 103 and a memory cell which does not include it may exist in one row of the memory cell array. In this way, the number of capacitors used as the by-pass capacitors can be changed with the number smaller than the number of memory cells included in one row of the memory cell array being one unit. Moreover, unlike the supply line 120 of one line as shown in FIG. 1, a supply line of multiple lines may be provided and the supply line of a different line may be connected to the second transistors 103 for each group of a predetermined number of columns or rows of the memory cell array. In other words, the supply line connected to the second transistors 103 may be different for each of groups of memory cells connected to a predetermined number of bit lines or word lines (i.e., cells, words, or blocks).

The semiconductor integrated circuit according to the first embodiment of the present invention adjusts the number of capacitors used as the by-pass capacitors among the capacitors of the memory cells included in the above-mentioned memory blocks.

The logic circuit unit 401 runs various programs (see FIG. 5). The programs include various applications 1, 2, and 3, an operating system (OS) 4, and a device driver 5. The applications 1, 2, and 3 request the OS 4 to use resources of the system (logic circuit unit 401, the memory core unit 410, the external memory unit M, and the like). The OS 4 manages the resources of the system and allocates devices and memory areas which should be actually used in response to the requests from the applications 1, 2, and 3. The device driver 5 actually controls the devices (the memory core unit 410, the external memory unit M, and the like) in accordance with the instruction from the OS 4.

A memory space of the system is managed by a memory management mechanism 4A included in the OS 4 (see FIG. 5). The memory management mechanism 4A particularly allocates a part of a logical memory space to physical memory areas of the memory core unit 410 and the external memory M, and manages the correspondence between them. Therefore, the applications 1, 2, and 3, in principle, can equally use the areas of the memory space of the system irrespective of hardware differences between the memory core unit 410 and the external memory M. In the first embodiment of the present invention, preferably, the memory management mechanism 4A manages areas of the memory cells which should be used as the by-pass capacitors (hereinafter, referred to as by-pass capacitor areas) for the memory core unit 410 along with the memory areas. Specifically, the memory management mechanism 4A relocates the memory areas and stored data in response to the request from the applications 1, 2, and 3 and also sets the by-pass capacitor areas again. In this way, the memory cells omitted from the memory areas can be used efficiently as the by-pass capacitors.

Accordingly, in the semiconductor integrated circuit according to the first embodiment of the present invention, the efficiency of use of the memory cells included in the memory core unit 410 is high, and the actual area of the memory core unit 410 can be made relatively small.

### Second Embodiment

A semiconductor integrated circuit according to the second embodiment of the present invention is formed similarly to the semiconductor integrated circuit 100 according to the first embodiment of the present invention except for an inner structure of the memory blocks included in the memory core unit 410. The description of the first embodiment and FIG. 4 are incorporated in this embodiment as descriptions for the details of the similar components.

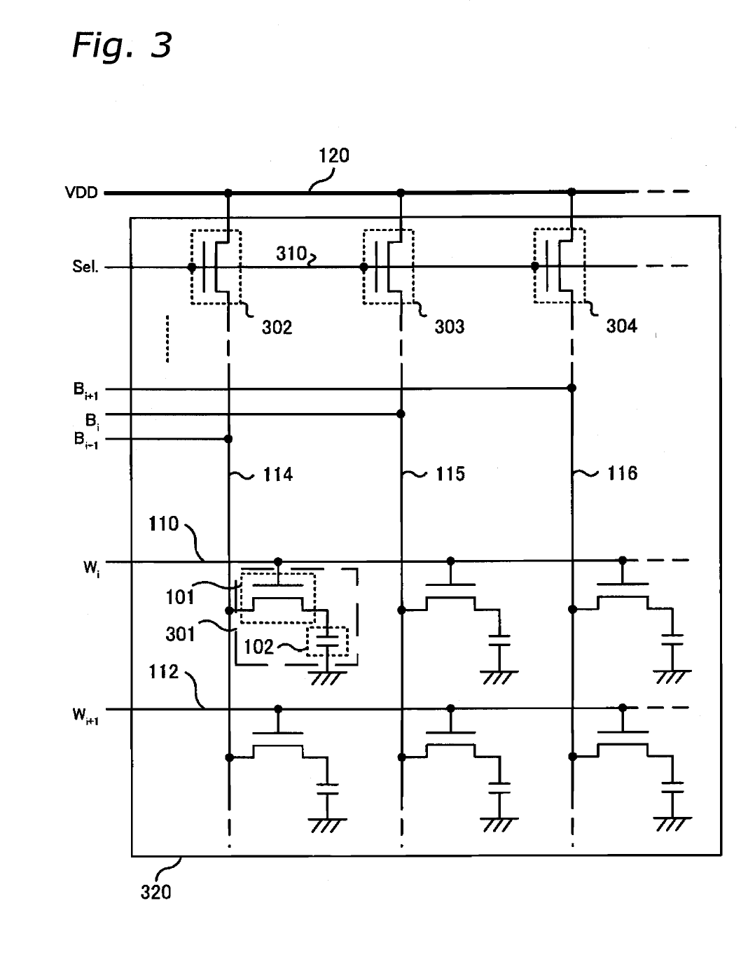

A memory block 320 preferably includes memory cells 301, word lines 110, 112, . . . , bit lines 114, 115, 116, . . . , a selector signal line 310, and third transistors 302, 303, 304, . . . (see FIG. 3). The memory cells 301 are preferably arranged in a matrix and form a memory cell array. The word lines 110, 112, . . . extend in a horizontal direction (row direction of the memory cell array) between the memory cells 301. The bit lines 114, 115, . . . extend in a vertical direction (column direction of the memory cell array) between the memory cells 301. Preferably, one selector signal line 310 is included in one memory block 320, and provided in parallel to the supply line 120. The third transistors 302, 303, 304, . . . are preferably MOSFETs having gates connected to the same selector signal line 310, sources connected to the same supply line 120 and drains connected to one of the bit lines 114, 115, 116, . . . . In other words, all the bit lines 114, 115, 116, . . . included in the memory block 320 are connected to the same supply line 120 via any one of the third transistors 302, 303, 304, . . . . Each of the memory cells 301 includes a first transistor 101 and a capacitor 102. The first transistor 101 is preferably a MOSFET having a gate connected to the closest word line 110, a source connected to the closest bit line 114 and a drain connected to one end of the capacitor 102. The other end of the capacitor 102 is grounded.

When the selector signal lines 310 is not active, the third transistors 302, 303, 304, . . . are all maintained at OFF state. Therefore, in all the memory cells 301 included in the memory block 320, the capacitors 102 function as memory by controlling ON/OFF state of the first transistors 101 by using the corresponding word lines 110, 112, . . . . On the other hand, when the selector signal line 310 is active, the third transistors 302, 303, 304, . . . are all maintained at ON state. Therefore, by the first transistors 101 connected to the active ones of the word lines 110, 112, . . . , the capacitors 102 of the same memory cell are connected to the supply line 120 via the bit lines 114, 115, 116, . . . . Accordingly, the capacitors 102 serve as by-pass capacitors, and suppress a potential change of the supply line 120.

In this way, in the memory block 320 according to the second embodiment of the present invention, as in the memory block according to the first embodiment, the capacitors 102 of the memory cells serve as both memory and the by-pass capacitors in accordance with states of the selector signal line 310, and the word lines 110, 112, . . . . Particularly, the number of capacitors used as the by-pass capacitors may be changed in units of rows of the memory cell array or in units of the memory blocks. In the memory block 320 according to the second embodiment of the present invention, unlike the memory block according to the first embodiment, the third transistors 302, 303, 304, . . . replace the second transistors 103 and are connected to the bit lines 114, 115, 116, . . . one-by-one. Therefore, in the second embodiment, the total number of the transistors and the number of the selector signal lines which should be included in one memory block are both smaller than those in the first embodiment. Further, a structure of individual memory cell does not have to be modified from the conventional structure. When the by-pass capacitor areas are set for the memory blocks 320 in such an example, preferably, the memory control unit 402 changes the state of the selector signal line 310 and also designates the word line to be activated to the memory core unit 410. Moreover, when the selector signal line 310 is activated, preferably all the word lines 110, 112, . . . may be activated automatically.

Unlike the arrangement shown in FIG. 3, one third transistor may be provided for a plurality of bit lines. In such a case, the number of capacitors used as the by-pass capacitors is changed with the number smaller than the total number of the capacitors included in one row of the memory cell array being one unit. Moreover, unlike one line of the supply line 120 as shown in FIG. 3, multiple lines of the supply line may be provided and the supply line of a different line may be connected to the third transistors for each group of a predetermined number of columns of the memory cell array.

### Third Embodiment

A semiconductor integrated circuit according to the third embodiment of the present invention is formed similarly to the semiconductor integrated circuit 100 according to the first embodiment of the present invention except for the selector signal lines and the memory core unit 410. The description of the first embodiment and FIGS. 1 and 4 are incorporated in this embodiment as description of the details of the similar components.

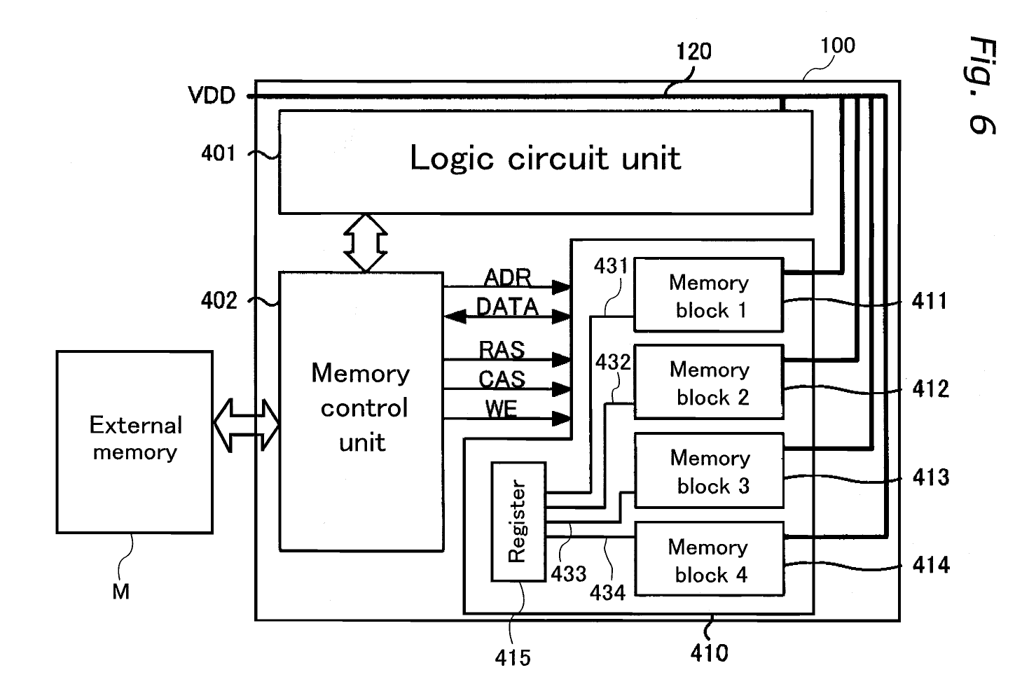

In the semiconductor integrated circuit according to the third embodiment of the present invention, unlike the semiconductor integrated circuit according to the first embodiment, a register 415 is provided inside the memory core unit 410 (see FIG. 6). Furthermore, instead of the selector signal lines 421, 422, 423, 424 connected between the memory control unit 402 and the memory blocks of the memory core unit 410 (see FIG. 4), selectors signal lines 431, 432, 433, 434 are connected between the register 415 and the memory blocks. The memory control unit 402 designates the number of capacitors in the memory cells used as the by-pass capacitors to the register 415 for each of the memory blocks. The value set to the register 415 may represent a ratio of the number of the memory cells between the memory areas and the by-pass capacitor areas. The memory core unit 410 controls states of the selector signal lines 431, 432, 433, and 434 based on the value set to the register 415. In this way, the number of the capacitors of the memory cells which should be connected to the supply line can be changed dynamically depending upon the process and the situation.

### INDUSTRIAL APPLICABILITY

The present invention relates to a semiconductor integrated circuit, particularly, to a semiconductor memory device incorporated therein. As described above, the number of capacitors used as the by-pass capacitors can be changed dynamically. Thus, the present invention is industrially applicable.

1-13. (canceled)

14. A semiconductor memory device comprising a plurality of bit lines lined in parallel, a plurality of word lines lined in parallel along a direction orthogonal to the bit lines, at least one selector signal line, at least one supply line, and a plurality of memory cells, wherein each of the memory cell includes:
a capacitor;
a first transistor which is controlled by one of the word lines, and connects the capacitor to one of the bit lines; and
a second transistor which is controlled by the selector signal line, and connects the capacitor directly to the supply line.

15. A semiconductor memory device according to claim 14, wherein a predetermined number of the second transistors are controlled by the same selector signal line.

16. A semiconductor memory device according to claim 14, wherein one selector signal line is provided for a predetermined number of the word lines.

17. A semiconductor memory device according to claim 14, wherein the supply line connected to the second transistor is different for each group of the memory cells connected to a predetermined number of the bit lines or the word lines.

18. A semiconductor integrated circuit comprising a semiconductor memory device which can connect and disconnect capacitors of memory cells to and from a supply line, the circuit which changes the number of the capacitors to be connected to the supply line in accordance with a process.

19. A semiconductor integrated circuit according to claim 18, further comprising:
a logic circuit unit for running predetermined applications; and
a memory control unit for controlling the semiconductor memory device in accordance with an instruction from the logic circuit unit, and particularly for changing the number of the capacitors to be connected to the supply line in accordance with a process.

20. A semiconductor memory device according to claim 19, the semiconductor memory device comprising:
a plurality of bit lines lined in parallel;
a plurality of word lines lined in parallel along a direction orthogonal to the bit lines;
a first transistor which is controlled by one of the word lines, and connects one of the capacitors to one of the bit lines;
a second transistor for connecting one of the capacitors or one of the bit lines to the supply line; and
a selector signal line for controlling the second transistor.

21. A semiconductor memory device according to claim 20, wherein the memory control unit controls the selector signal line in accordance with a process.

22. A semiconductor memory device according to claim 20, wherein:
the semiconductor memory device further, includes a register for controlling the selector signal line; and
the memory control unit controls the register in accordance with a process.
